(19) United States
(12) Patent Application Publication
(10) Pub. No.: US 2009/0256142 A1
(43) Pub. Date: Oct. 15, 2009

(54) ORGANIC THIN FILM TRANSISTOR AND METHOD FOR MANUFACTURING SAME

(75) Inventor: Katsura Hirai, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA HOLDINGS, INC., Tokyo (JP)

(21) Appl. No.: 12/375,283

(22) PCT Filed: Jul. 17, 2007
(86) PCT No.: PCT/JP2007/064069

§ 371 Date: Jan. 27, 2009

(30) Foreign Application Priority Data
Aug. 8, 2006 (JP) 2006 215506

(51) Int. Cl. H01L 51/10; H01L 51/40; H01L 21/336

(52) U.S. Cl. 257/40; 438/99; 257/66; 257/E51.006; 257/E21.411

(57) ABSTRACT

Disclosed are an organic thin film transistor exhibiting a high switching current value even when a distance (channel length) between source and the drain electrodes is large, and a manufacturing method thereof. The organic thin film transistor of the invention comprises a substrate, a gate electrode, a gate insulating layer, an organic semiconductor layer, a source electrode, a drain electrode and at least one different type electrodes characterized in that the different type electrode is formed in a channel region between the source electrode and the drain electrode on the organic semiconductor layer.

### TECHNICAL FIELD

The present invention relates to an organic thin film transistor with high carrier mobility and a method for manufacturing the organic thin film transistor.

### TECHNICAL BACKGROUND

Since film formation conditions for devices employing organic semiconductors are milder than those for conventional inorganic semiconductor devices, it is possible to form semiconductor thin films on various substrates and to perform film formation at room temperature, whereby cost reduction, and flexibility of thin films due to the formation thereof on polymer films have been anticipated.

As organic semiconductor materials, conjugated polymers and oligomers such as polyphenylvinylene, polypyrrole, polythiophene, or oligothiophene, as well as polyacene compounds such as anthracene, tetracene, or pentacene have been investigated.

As methods for forming electrodes in the devices employing organic semiconductors above, there is employed a method for forming an electrode pattern via etching or lift-off of a uniformly formed metal thin film or a method for forming an electrode pattern by printing a coating containing a metal tiller or a conductive polymer solution.

For example, Patent Document 1 describes that a low resistance electrode is readily formed employing electroless plating. This is a method wherein an electrode pattern is readily formed employing a catalyst inducing electroless plating, a plating agent, or in combination thereof with patterning such as printing therewith, whereby electrode pattern formation is possible without complex steps.

The organic thin film transistor has advantages in that it can be manufactured through a relatively rough process such as printing as described above. However, when the constituents such as an electrode are formed through printing, problems are likely to be produced in the size or the positioning accuracy, and therefore, there is restriction that it is necessary to increase a distance (channel length) between a source electrode and a drain electrode in order to prevent short circuit. On the other hand, when the channel length is increased, problem is produced that current value to flow in an organic thin film transistor lowers.

### Patent Document No. 1: 2004-158805

### DISCLOSURE OF THE INVENTION

### Problems to be Solved by the Invention

An object of the invention is to provide an organic thin film transistor exhibiting a high switching current value even when a distance (channel length) between source and the drain electrodes is large, and a manufacturing method thereof.

### Means for Solving the Problems

The above object has been attained by any one of the following constitutions.

1. An organic thin film transistor comprising a substrate, a gate electrode, a gate insulating layer, an organic semiconductor layer, a source electrode, a drain electrode and at least one different type electrode, characterized in that the different type electrode is provided on the organic semiconductor layer and in a channel region between the source electrode and the drain electrode.

2. The organic thin film transistor of item 1 above, characterized in that the different type electrode is independently provided.

3. The organic thin film transistor of item 1 or 2 above, characterized in that the different type electrode is formed from fluid electrode materials.

4. The organic thin film transistor of any one of items 1 through 3 above, characterized in that the source electrode and the drain electrode are formed from fluid electrode materials.

5. The organic thin film transistor of any one of items 1 through 4 above, characterized in that the fluid electrode materials for forming the different type electrode contain water.

6. The organic thin film transistor of any one of items 1 through 5 above, characterized in that the contact angle of the organic semiconductor layer surface to water is at least

7. The organic thin film transistor of any one of items 1 through 6 above, characterized in that the organic semiconductor layer is a solution casting layer.

8. A method for manufacturing an organic thin film transistor comprising a substrate, a gate electrode, a gate insulating layer, an organic semiconductor layer, a source electrode, a drain electrode and at least one different type electrode, the method comprising the step of forming the different type electrode on the organic semiconductor layer and in a channel region between the source electrode and the drain electrode.

### EFFECTS OF THE INVENTION

The present invention can provide an organic thin film transistor exhibiting a high switching current value even when a distance (channel length) between source and the drain electrodes is large, and a manufacturing method thereof.

### BRIEF DESCRIPTION OF DRAWINGS

FIG. 1 is a diagram showing a structure of the organic thin film transistor element of the invention.

FIG. 2 is a schematic diagram showing a pattern example of the different type electrode in the invention.

FIG. 3 is a schematic diagram of the equivalent circuit of one example of the organic thin film transistor element sheet of the invention.

FIG. 4 is an illustration for explaining a manufacturing method of the organic thin film transistor element (of top contact type) of the invention.

### EXPLANATION OF SYMBOLS

1. Substrate (Base Plate)
2. Gate electrode
3. Gate insulating layer
4. Organic semiconductor layer
5. Source electrode
6. Drain electrode
7. Different type electrode
11. Substrate
12. Gate electrode
13. Gate insulating layer
14. Organic semiconductor layer
15. Source electrode
16. Drain electrode
17. Different type electrode
18. Subbing layer
20. Organic thin film transistor
21. Gate busline
22. Source busline
24. Organic thin film transistor element
25. Accumulation capacitor
26. Output element
27. Vertical drive circuit
28. Horizontal drive circuit

### PREFERRED EMBODIMENT OF THE INVENTION

Next, the invention and constitution thereof will be explained in detail.

### [Organic Thin Film Transistor]

The organic thin film transistor (hereinafter also referred to, as organic TFT or simply as TFT) of the invention comprises a substrate, a gate electrode, a gate insulating layer, an organic semiconductor layer, a source electrode, a drain electrode and at least one different type electrode, characterized in that the different type electrode is provided on the organic semiconductor layer and in a channel region between the source electrode and the drain electrode.

The present inventors have found that the top contact type structure described later provides a TFT with high mobility enabling stable operation.

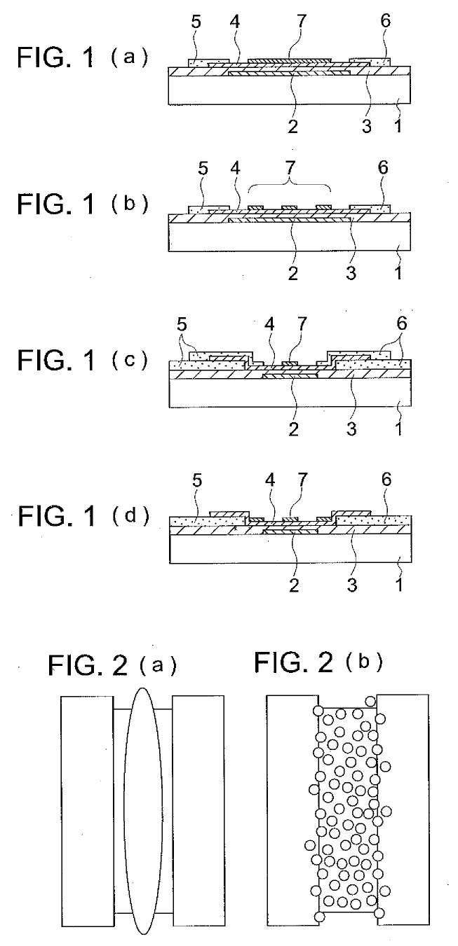

The structures suitable for a top contact type organic thin film transistor of the invention are shown in FIGS. 1(a) through 1(d).

The structure of FIG. 1(a) is a so-called top contact type structure in which a gate electrode 2 and a gate insulating layer 3 are provided on a substrate 1 in that order, an organic semiconductor layer 4, a source electrode 5 and a drain electrode 6 are formed to be in direct contact with the gate insulating layer 3, a different type electrode 7 is formed on the organic semiconductor layer 4, and the source electrode 5, the drain electrode 6 and the different type electrode 7 are in direct contact with the upper surface of the organic semiconductor. Accordingly, each electrode is formed after formation of the organic semiconductor layer.

The different type electrode 7 is provided independent of the source electrode 5 and the drain electrode 6. The different type electrode 7 brings about an effect substantially reducing a distance (channel length) between the source electrode and the drain electrode.

The structure of FIG. 1(b) is the same as that of FIG. 1(a), except that a plurality of different type electrodes 7 are provided on the semiconductor layer 4, resulting in further substantial reduction of the channel length.

The structure of FIG. 1(c) is a structure in which after the source electrode 5 and the drain electrode 6 are provided on the gate insulating layer 3, the organic semiconductor layer 4 is formed, followed by formation of source electrode 5, drain electrode 6 and the different type electrode 7.

The structure of FIG. 1(d) is a structure in which after the source electrode 5 and the drain electrode 6 are provided on the gate insulating layer 3, the organic semiconductor layer 4 is formed, followed by formation of the different type electrode 7.

### <Constitution and Formation Process of Different Type Electrode>

It is preferred that the different type electrode in the invention is formed through a printing method employing fluid electrode materials or a solution process such as coating. A pattern as shown in FIG. 1(a) is preferably formed according to for example, a printing method, employing a dispersion of metal particles or a conductive polymer such as polyethylenedioxy thiophene-polystyrene sulfonic acid complex (PEDOT-PSS).

Alternatively, a pattern in the dot form can be also formed as shown in FIG. 2(b). The dots may partially overlap each other as long as they do not cause electrical conduction between the source electrode and drain electrode. It is preferred in simplifying the process that self-organizing dots are formed as shown in FIG. 2(b), employing the phenomenon (liquid-repellent property) that a coating is repelled after the coating is formed in the entire channel region. Since an organic semiconductor suitably used in an organic thin film transistor is oleophilic, the contact angle to water of the organic semiconductor layer is maintained high. Accordingly, when a different type-electrode is used employing the liquid-repellent property, a water-soluble or water-dispersible fluid electrode material is preferably employed.

### <Fluid Electrode Material>

The conductivity of the different type electrode in the invention is not less than 0.001 S/cm, and preferably not less than 1 S/cm.

The fluid electrode material in the invention is typically a solution, paste, ink, metal film precursor material or dispersion containing conductive materials as described later.

In the above fluid electrode material to be supplied from an ink jet apparatus, the solvent or dispersion medium contains water of preferably not less than 50% by weight.

The conductive materials are not specifically limited provided that the materials have conductivity sufficient to be put into practical use as electrodes. Examples thereof include platinum, gold, silver, nickel, chromium, copper, iron, tin, antimony lead, tantalum, indium, palladium, tellurium, rhenium, iridium, aluminum, ruthenium, germanium, molybdenum, tungsten, tin oxide-antimony, indium oxide-tin (ITO), fluorine-doped zinc oxide, zinc, carbon, graphite, glassy carbon, silver paste and carbon paste, lithium, beryllium, sodium, magnesium, potassium, calcium, scandium, titanium, manganese, zirconium, gallium, niobium, sodium, sodium-potassium alloy, magnesium, lithium, aluminum, magnesium/copper mixtures, magnesium/silver mixtures, magnesium/aluminum mixtures, magnesium/indium mixtures, aluminum/aluminum oxide mixtures, and lithium/aluminum mixtures. Platinum, gold, silver, copper, indium, aluminum, indium oxide-tin (ITO) and carbon are preferred.

As the conductive materials, conductive polymers or metal particles are suitably used. As the dispersion containing metal particles, known electrically conductive pastes may be used, but a dispersion containing metal particles with a particle size of from 1 to 50 nm, and preferably from 1 to 10 nm, is preferably used.

Materials for the metal particles include platinum, gold, silver, nickel, chromium, copper, iron, tin, antimony, lead, tantalum, indium, palladium, tellurium, rhenium, iridium, aluminum, ruthenium, germanium, molybdenum, tungsten, and zinc.

Methods for preparing such a metal particle dispersion include a physical preparation method such as an in-gas vaporization method, a sputtering method, or a metallic vapor preparation method and a chemical preparation method such as a colloid method or a co-precipitation method in which metal ions are reduced in a liquid phase to produce metal particles. The metal particle dispersions are preferably ones prepared according to a colloid method disclosed in Japanese Patent O.P.I. Publication Nos. 11-76800, 11-80647, 11-319538, and 2000-239853, or ones prepared according to a gas vaporization method disclosed in Japanese Patent O.P.I. Publication Nos. 2001-254185, 2001-53028, 2001-35255, 2000-124157 and 2000-123634

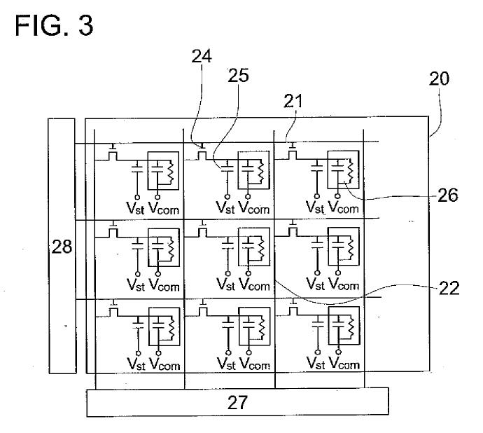

FIG. 3 is a schematic equivalent circuit diagram of one example of the organic thin film transistor element sheet 20, wherein a plurality of the thin film transistor element of the present invention is arranged.

Thin film transistor sheet 20 comprises a number of thin film transistor elements 24 matrix-arranged. The symbol 21 represents a gate busline for the gate electrode of each of thin film transistor elements 24, and the symbol 22 represents a source busline for the source electrode of each of thin film transistor elements 24. The drain electrode of each of thin film transistor elements 14 is connected with output element 26, which is, for example, a liquid crystal or an electphoretic element, and which constitutes a pixel of a display. In the illustrated example, a liquid crystal serving as output element 26 is shown with an equivalent circuit composed of a resistor and a capacitor. The symbols 25, 27, and 28 represent an accumulation capacitor, a vertical drive circuit, and a horizontal drive circuit, respectively.

The method of the present invention can be used for preparation of such a thin film transistor sheet with two-dimensional arrangement of organic TFT elements on a substrate.

### (Electrode Formation Method)

As a method of forming an electrode such as a source, a drain, or a gate electrode, a gate or a source busline in the thin film transistor (element sheet) in the invention without pattering of a metal thin film using a light sensitive resin such as etching or lift-off, there is known one employing an electroless plating method.

In forming methods of electrodes via the electroless plating method, as described in Japanese Patent O.P.I. Publication No. 2004-158805, a liquid containing a plating catalyst inducing electroless plating on reaction with a plating agent is patterned on portions where an electrode is provided, for example, via a printing method (including an ink-jet method), followed by allowing the plating agent to be brought into contact with the portions where an electrode is provided. Thus, electroless plating is carried out on the above portions via contact of the catalyst with the plating agent to form an electrode pattern.

The catalyst and the plating agent may reversely be employed in such electroless plating, and also pattern formation may be conducted using either thereof. However, it is preferred to employ a method of forming a plating catalyst pattern and then applying a plating agent thereto.

As the printing method, printing such as screen printing, lithographic printing, letterpress printing, intaglio printing or ink jet printing is employed. However, patterning of the plating catalyst or plating agent according to these printing methods is insufficient in accuracy, when a circuit pattern with high precision is required.

The present inventor has made an extensive study, and as a result, he has found that a printing method, in which printing is carried out employing a plating catalyst-containing solution and an electrostatic suction type liquid ejecting apparatus instead of employing a printing method or an conventional ink jet method, is suitable for printing with high precision and forms an electrode pattern with high accuracy according to electroless plating, whereby an electrode pattern with a low electrical resistance and high precision can be easily obtained.

### <Electroless Plating Method>

The electroless plating method will be described below.

Catalysts inducing electroless plating on reaction with a plating agent are composed of at least a compound selected from Pd, Rh, Pt, Ru, Os, and Ir, an ion thereof or metal fine particles.

Specifically, there are applicable halides such as chlorides, bromides, or fluorides; inorganic salts or complex salts such as sulfates, nitrates, phosphates, borates, or cyanides; a single substance selected from organic complex salts such as carboxylates, organic sulfonates, organic phosphates, alkyl complexes, alkane complexes, alkene complexes, cyclopentadiene complexes, porphyrin, or phthalocyanine, or a mixture thereof; ions of the above elements; and metal fine particles of the above elements. Incidentally, a solution or dispersion containing a surfactant or a resin binder may be added to a catalyst composed of the organic complex salt.

As a plating agent, there is utilized, for example, a solution, in which an ion of a metal to be deposited as an electrode is homogeneously dissolved, and a reducing agent is contained in combination with a metal salt. Herein, a plating agent used is ordinarily a solution but is not limited thereto as long as it is capable of inducing electroless plating, and a gaseous or a powder plating agent may also be used.

Specifically, as the metal salt, applicable are a metal halide, nitrate, sulfate, phosphate, borate, acetate, tartrate, and citrate. Further, as the reducing agent, applicable are hydrazine, a hydrazine salt, borohalide, hypophosphite, hyposulfite, alcohol, aldehyde, carboxylic acid, and carboxylate. Herein, any element such as boron, phosphor or nitrogen contained in the reducing agent may be contained in an electrode to be deposited.

As the plating agent, a mixture of the metal salt and the reducing agent may be applicable, and the metal salt or the reducing agent may be applicable individually, also. Herein, in order to form an electrode pattern more sharply, a mixture of the metal salt and the reducing agent is preferably applied. Further, when the metal salt or the reducing agent is applied individually, the metal salt is initially applied on a portion where the electrode is formed, and then the reducing agent is applied to the portions where the metal salt has been applied, resulting in formation of a more stable electrode pattern.

The plating agent may contain additives such as a buffering agent for pH control or a surfactant, as necessary. Further, an organic solvent other than water such as alcohol, ketone or ester may be added as a solvent used for the solution.

A composition of the plating agent is composed of a salt of a metal to be deposited, a reducing agent, and optionally an additive or an organic solvent, and the concentration and the composition may be adjusted depending on the deposition rate. The deposition rate may also be adjusted by controlling the temperature of the plating agent. Methods to control this temperature include a method controlling the temperature of the plating agent and a method controlling the temperature by heating or cooling a substrate before being immersed in the plating agent. The film thickness of a metal thin film to be deposited may also be adjusted via a period during which the substrate is immersed in the plating agent.

In the invention, as a method printing a solution containing the electroless plating catalyst, a conventional printing method such as screen printing, letterpress printing, lithographic printing or intaglio printing or a solution jetting apparatus employing an electrostatic suction method instead of a conventional ink jet method is preferably used. A pattern of the electroless plating catalyst is formed according to the solution jetting apparatus employing an electrostatic suction method, and a plating agent is brought in contact with the pattern, whereby electroless plating is carried out. Thus, an electrode pattern is obtained which is composed of a metal thin layer formed via the electroless plating.

The contact of the plating agent can be carried out by a coating method, a spray method or an immersion method. The plating agent may be pattern-printed in the regions including portions where a plating catalyst pattern has been formed in the same manner as the plating catalyst pattern. A printing method such as ink jetting, screen printing, intaglio printing, lithographic printing or letterpress printing or a solution jetting apparatus employing an electrostatic suction method may be used. After the electrode pattern is formed via electroless plating, a solute, which is contained in the plating agent, adhered to the surface of the substrate is washed away, as necessary.

The plating agent and the plating catalyst may be used in the reverse order. Pattering may be carried out employing the plating agent.

The electrode formed via electroless plating is composed of at least one kind of metal selected from Au, Ag, Cu, Ni, Co, Fe and an alloy thereof. Herein, the metal also includes an intermetallic compound.

Examples of the electrostatic suction type liquid ejecting apparatus include those described in Japanese Patent O.P.I. Publication Nos. 8-238774 and 2000-127410, and apparatus similar to these can be advantageously employed.

The electrostatic suction type is a method which can eject minute liquid particles. Since the ejected particles receive electrostatic force during flight in addition to energy for ejecting, ejecting energy per unit volume can be reduced. Accordingly, the method of the electrostatic suction type can be applied to ejection of minute liquid particles, which enables printing pattern with high precision.

In the invention, the source and drain electrodes are preferably formed according to the electroless plating method described above. The method is preferably used when a source electrode, a drain electrode and a source busline are simultaneously formed.

The method employing the electrostatic suction type liquid ejecting apparatus is suitable for manufacturing a thin film transistor having a bottom-gate type structure. This method is preferred since patterning of a source electrode, a source busline and a drain electrode can be carried out with high accuracy on a substrate on which a gate electrode, a gate busline, a gate insulating film (layer), or a semiconductor film (layer) is provided, eliminating a complex process employing resist formation.

The method of manufacturing a thin film transistor employing the electrostatic suction type liquid ejecting apparatus is especially advantageously employed in manufacturing an organic thin film transistor. The method of the invention is preferred since when a source electrode and a drain electrode are formed on an organic semiconductor layer, patterning can be carried out with high accuracy and with ease, without using a process employing resist formation. Further, the method of the invention is preferred particularly when organic semiconductor materials are used, since when a light sensitive resin is used in patterning of an electrode, the light sensitive resin itself or a process forming or removing a resist thereof is restricted to those having no adverse effect on an organic semiconductor layer.

In the thin film transistor regarding the invention, when an electrode is formed on an organic semiconductor layer according to electroless plating, it is preferred that the organic semiconductor layer in a region (for example, a region to form a semiconductor channel in a thin film transistor element) other than where an electrode is to be formed is not in direct contact with the plating catalyst or plating agent which is considered to have an influence on the organic conductor material. Accordingly, when a thin film transistor having a top contact type structure is manufactured, an organic semiconductor layer protective layer is preferably provided in a necessary region other than where an electrode is to be formed.

The protective layer is preferably formed to protect a region to be protected (for example, a region to form a semiconductor channel) other than where an electrode is to be formed. After the protective layer formation, electroless plating is carried out in which a plating catalyst pattern is formed, and then the plating agent is brought into contact with the plating catalyst pattern. The plating agent contact method is not specifically limited; but for example, a method spraying the plating agent or immersing in the plating agent, or a printing method such as ink-jetting, screen printing, intaglio printing, lithographic printing or letterpress printing is applicable.

After the electrode thin layer pattern is formed via electroless plating, a solute, which is contained in the plating agent, adhered to the surface of the substrate is washed away, as necessary.

### (Protective Layer)

In the present invention, as a protective layer formed on an organic semiconductor film (layer) prior to arrangement of an electrode via the electroless plating, there may be applicable any inert material which has no adverse effect on the organic semiconductor material, and also inhibits the action of the plating catalyst as well as the metal salt and the reducing agent contained in the plating agent. When a light sensitive composition such as a light sensitive resin layer is formed on the organic semiconductor protective layer, a material, which is unaffected in the coating process as well as during the patterning of the light sensitive resin layer, is preferred.

Examples of such a material include polymer materials described later, specifically, materials containing a hydrophilic polymer. Further, a solution or an aqueous dispersion of the hydrophilic polymer is preferred.

The hydrophilic polymer is one having solubility or dispersibility to water, an acidic aqueous solution, an alkaline aqueous solution, an alcoholic aqueous solution or aqueous solutions containing various surfactants. For example, polyvinyl alcohol, and a homopolymer or a copolymer composed of a component such as HEMA, acrylic acid or acrylamide are preferably utilized. Other materials such as materials containing an inorganic oxide or an inorganic nitride are also preferred, since they have no adverse effect on the organic semiconductor as well as on the coating process. Further, materials used for a gate insulating layer described later may be utilized.

An organic semiconductor protective layer containing an inorganic oxide or an inorganic nitride, which is a gate insulating layer material, is preferably formed via an atmospheric pressure plasma method.

The insulating film formation method according to plasma at atmospheric pressure means a method wherein a reactive gas is plasma-excited by discharge conducted at atmospheric pressure or at approximately atmospheric pressure, whereby a thin-film is formed on a substrate. The method (hereinafter referred to also as an atmospheric pressure plasma method) is described in Japanese Patent O.P.I. Publication Nos. 11-61406, 11-133205, 2000-121804, 2000-147209, and 2000-185362. This method can form a thin layer having high performance at high productivity.

Further, a photoresist is preferably utilized for patterning the protective layer.

A negative or positive working material known in the art may be utilized for the photoresist layer, but laser-sensitive materials are preferably utilized. Materials for the photoresist include (1) photopolymerizable light sensitive materials of a dye-sensitized type as described in Japanese Patent O.P.I. Publication Nos. 11-271969, 2001-117219, 11-311859, and 11-352691; (2) negative working light sensitive materials featuring infrared laser sensitivity as described in Japanese Patent O.P.I. Publication No. 9-179292, U.S. Pat. No. 5,340,699, Japanese Patent O.P.I. Publication Nos. 10-90885, 2000-321780, and 2001-154374; and (3) positive working light sensitive materials featuring infrared laser sensitivity as described in Japanese Patent O.P.I. Publication Nos. 9-171254, 5-115144, 10-87733, 9-43847, 10-268512, 11-194504, 11-223936, 11-84657, 11-174681, 7-285275, and 2000-56452, and WO 97/39894 and 98/42507. The materials described in (2) and (3) above are preferred in that the process does not require a dark room, but the materials described in (3) above, which is positive working, are most preferred in a process comprising removing the photoresist layer.

Solvents to prepare a coating solution of the light sensitive resin include propylene glycol monomethyl ether, propylene glycol monoethyl ether, methyl cellosolve, methyl cellosolve acetate, ethyl cellosolve, ethyl cellosolve acetate, dimethylformamide, dimethylsulfoxide, dioxane, acetone, cyclohexanone, trichloroethylene, and methyl ethyl ketone. These solvents may be used singly or as an admixture of two or more kinds thereof.

Methods for forming the light sensitive resin layer include coating methods such as a spray coating method, a spin coating method, a blade coating method, a dip coating method, a casting method, a roll coating method, a bar coating method and a die coating method, as described above in patterning of the protective layer.

After formation of the light sensitive resin layer, a pattern exposure is carried out using an Ar laser, a semiconductor laser, a He-Ne laser, a YAG laser, or a carbon dioxide gas laser. A semiconductor laser having an infrared emission wavelength is preferred. The output power thereof is appropriately at least 50 mW, but preferably at least 100 mW.

As a developing solution used to develop the light sensitive resin layer, an aqueous alkaline developing solution is preferred. Examples thereof include, for example, aqueous solutions of alkali metal salts such as sodium hydroxide, potassium hydroxide, sodium carbonate, potassium carbonate, sodium metasilicate, potassium metasilicate, sodium secondary phosphate, or sodium tertiary phosphate; and aqueous solutions prepared by dissolving alkali compounds such as ammonia, ethylamine, n-propylamine, diethylamine, di-n-propylamine, triethylamine, methyldiethylamine, dimethylethanolamine, triethanolamine, tetramethylammonium hydroxide, piperidine or 1,8-diazabicyclo-[5,4,0]-7-undecene. The concentration of the alkali compound in the alkaline developing solution of the present invention is ordinarily from 1 to 10% by weight, and preferably from 2 to 5% by weight.

An anionic surfactant, an amphoteric surfactant, or an organic solvent such as alcohol may optionally be added in the developing solution. Applicable examples of the organic solvent include propylene glycol, ethylene glycol monophenyl ether, benzyl alcohol, and n-propyl alcohol.

In the present invention, an ablation layer, which is another light sensitive resin layer, may be used to form a plating catalyst pattern of the protective layer, that is, an electrode pattern.

The ablation layer in the present invention may be structured of an energy light absorbent, a binder resin, and optionally various additives.

As the energy light absorbent, various inorganic or organic materials, which absorb energy light for irradiation, may be utilized. For example, when an infrared laser is used as the laser light source, there may be utilized a pigment, a dye, metal, a metal oxide, a metal nitride, a metal carbide, a metal boride, graphite, carbon black, titanium black, and ferromagnetic metal powders such as magnetic metal powders containing Al. Fe, Ni, or Co as the main component, all of which absorb infrared rays. Of these, carbon black, a dye such as a cyanine dye, and Fe based ferromagnetic metal powders are preferred. The content of the energy light absorbent is from 30 to 95% by weight, and preferably from 40 to 80% by weight based on the ablation layer-forming composition.

A binder resin used in the ablation layer is not specifically limited provided that the resin adequately carries the energy light absorbent described above, for example, fine colorant particles. Examples thereof include a polyurethane resin, a polyester resin, a vinyl chloride resin, a polyvinyl acetal resin, a cellulose resin, an acryl resin, a phenoxy resin, a polycarbonate, a polyamide resin, a phenol resin, and an epoxy resin. The content of the binder resin is from 5 to 70% by weight, and preferably from 20 to GO % by weight, based on the ablation layer-forming composition.

The ablation layer according to the present specification refers to a layer ablated by irradiating high-density energy light, and “ablation” herein means those phenomena in that the ablation layer is completely or partially scattered, or partially destroyed via a physical or chemical change, or some certain physical or chemical changes occur only at the vicinity of the interface between the ablation layer and its adjacent layer. An electrode is formed via formation of a resist image employing the ablation.

The high-density energy light is not specifically limited provided that the light is actinic light causing the ablation. An exposure method may include a method of flash exposure through a photomask using a xenon lamp, a halogen lamp, or a mercury lamp, or a method of scanning exposure via convergence of laser rays. An infrared laser with an output power of 20 to 200 mW per laser beam, specifically a semiconductor laser, is most preferably utilized. The energy density is preferably from 50 to 500 mJ/cm², and more preferably from 100 to 300 mJ/cm².

Further, an electrode material-repellent layer with a thickness of about 0.5 μm is preferably formed on the light sensitive resin layer via solvent coating.

The electrode material-repellent layer refers to a silicone rubber layer or a layer which provides the surface of a light sensitive layer with repulsion properties against an electrode material, that is, the plating catalyst liquid or the plating agent liquid according to the present invention. Patterning is carried out via combination with the light sensitive layer, wherein the electrode material-repellent layer is coated on the light sensitive layer and then the coated light sensitive layer is exposed or developed. For the light sensitive layer, an ablation layer or a photopolymerizable light sensitive material is preferably employed.

For example, the light sensitive layer and electrode material-repellent layer thus formed is exposed to form a pattern of a source electrode or a source busline, using a semiconductor laser, followed by removing the electrode material-repellent layer (the silicone rubber layer) at the exposed portions through brushing treatment. Since adhesion between the light sensitive layer and the silicone rubber layer is changed, the silicone rubber layer can be readily removed via the brushing treatment.

The resulting element was sufficiently washed with water, the light sensitive layer or for example, the protective layer composed of polyvinyl alcohol at exposed portions are dissolved and then removed, whereby the protective layer is removed to expose an organic semiconductor thin layer in the region to be subjected to electroless plating.

Via combination of the electrode material-repellent layer and the electroless plating materials, the effect of the protective layer can be enhanced, whereby patterning can be carried out with high accuracy only at the portions where electrodes are to be formed and also the patterning of the electrode material can be conducted via a simple process.

After the formation of the electrodes, the resist image may be removed. In order to remove the resist image, an appropriate solvent used is selected from a wide range of organic solvents used as a coating solvent for a photoresist such as alcohol, ether, ester, ketone or glycol ether. Of these, a preferred solvent is one that does not corrode the organic semiconductor layer.

Patterning of the protective layer can be carried out employing an electrostatic suction type liquid ejecting apparatus. Direct patterning of the protective layer can be carried out by ejecting, as ink, a protective layer material-containing solution employing the electrostatic suction type liquid ejecting apparatus instead of a method according to resist formation. Particularly, use of the electrostatic suction type liquid ejecting apparatus can easily form the same pattern with high accuracy as in the resist formation method.

The protective layer may be removed after electrode formation. For example, in the top-contact type thin film transistor, when a plating agent solution adhered to the substrate surface after formation of source and drain electrodes is washed away, the protective layer is preferably removed. However, the protective layer may be left as long as it has no adverse effect on performance of the thin film transistor.

Next, other constituents of the organic thin film transistor constituting the invention will be explained.

### (Organic Semiconductor Film (Layer))

Various conjugated compounds or condensed polycyclic aromatic compounds or are applicable to materials constituting the organic semiconductor film (also referred to as organic semiconductor layer).

Examples of the condensed polycyclic aromatic compounds include compounds such as anthracene, tetracene, pentacene, hexacene, heptacene, chrysene, pysene, fuluminene, pyrene, peropyrene, perylene, terylene, quoterylene, coronene, ovalene, circumanthracene, bisanthene, sesulene, heptasesulene, pyranthrene, violanthene, isoviolanthene, circobiphenyl, phthalocyanine and porphyrin; and derivatives thereof.

Examples of the conjugated compounds include polythiophene and oligomers thereof, polypyrrole and oligomers thereof, polyaniline, polyphenylene and oligomers thereof, polyphenylene vinylene and oligomers thereof, polythienylene vinylene and oligomers thereof, polyacetylene, polydiacetylene, tetrathiafluvalene compounds, quinone compounds, cyano compounds such as tetracyanoquinodimethane, fullerene and their derivatives or mixtures.

Specifically, of polythiophene and oligomers thereof, there may preferably be utilized oligomers such as a thiophene hexamers for example, α-sexithiophene, α,ω-dihexyl-α-sexithiophene, α,ω-dihexyl-α-quinquethiophene and α,ω-bis(3-butoxypropyl)-α-sexithiophene.

Further, listed are metallophthalocyanines such as copper phthalocyanine, and fluorine-substituted copper phthalocyanines described in Japanese Patent O.P.I. Publication No. 11-251601; tetracarboxylic acid diimides of condensed ring compounds including naphthalene tetracarboxylic acid imides such as naphthalene 1,4,5,8-teracarboxylic acid diimide, N,N′-bis(4-trifluoromethylbenzyl)naphthalene 1,4,5,8-tretracarboxylic acid diimide, N,N′-bis(1H,1H-perfluoroctyl)naphthalene 1,4,5,8-tetracarboxylic acid diimide derivatives, N,N′-bis(1H, 1H-perfluorobutyl)naphthalene 1,4,5,8-tetracarboxylic acid diimide derivatives, N,N′-dioctylnaphthalene 1,4,5,8 tetracarboxylic acid diimide derivatives, and naphthalene 2,3,6,7-tetracarboxylic acid diimides, and anthracene tetracarbocylic acid diimides such as anthracene 2,3,6,7-tetracarboxylic acid diimides; fullerenes such as C₆₀, C₇₀, C₇₆, C₇₈, and C₈₄; carbon nanotubes such as SWNT; and dyes such as merocyanine dyes and hemicyanine dyes.

Of these π conjugate compounds, preferably employed is at least one selected from the group consisting of condensed polycyclic aromatic compounds such as pentacene, fullerenes, tetracarboxylic acid diimides of condensed ring compounds, and metallo-phthalocyanines.

Further, as the organic semiconductor material of the present invention, preferred also are silylethynylpentacene compounds described in Adv. Mater., 2003, 15, No. 23, Dec. 3 (2009-2011) and compounds having acene or heteroacene as the mother nucleus described in J. Am. Chem. Soc., 2005, 127, 4986-4987, and silylethynylpentacene, trisalkylsilylethynylpentacene or triisopropylsilylethynyl-pentacene is preferably used.

Still further, other organic semiconductor materials used may also include organic molecular complexes such as tetrathiafluvalene (TTF)-tetracyanoguinodimethane (TCNQ) complexes, bisethylenetetrathiafluvalene (BEDTTTF)-perchloric acid complexes, BEDTTTF-iodine complexes, or TCNQ-iodine complexes. Additionally, there may be utilized σ-conjugated polymers such as polysilane or polygerman, and organic-inorganic composite materials described in Japanese Patent O.P.I. Publication No. 2000-260999.

In the invention, the organic semiconductor layer may be subjected to a so-called doping treatment which incorporates materials working as an acceptor which accepts electrons, for example, acrylic acid, acetamide, materials having a functional group such as a dimethylamino group, a cyano group, a carboxyl group and a nitro group, benzoquinone derivatives, or tetracyanoethylene, tetracyanoquinodimethane or their derivatives, or materials working as a donor which donates electrons, for example, materials having a functional group such as an amino group, a triphenyl group, an alkyl group, a hydroxyl group, an alkoxy group, and a phenyl group; substituted amines such as phenylenediamine; anthracene, benzoanthracene, substituted benzoanthracenes, pyrene, substituted pyrene, carbazole and its derivatives, and tetrathiafulvalene and its derivatives.

The doping herein means that an electron accepting molecule (acceptor) or an electron donating molecule (donor) is incorporated in the organic semiconductor layer as a dopant. Accordingly, the layer, which has been subjected to doping, is one which comprises the condensed polycyclic aromatic compounds and the dopant. As the dopant in the present invention, a known dopant can be used.

The organic semiconductor layer can be formed via methods known in the art, including, for example, vacuum deposition, MBE (Molecular Beam Epitaxy), an ion cluster beam method, a low-energy ion beam method, an ion plating method, a sputtering method, CVD (Chemical Vapor Deposition), laser deposition, electron beam deposition, electrodeposition, spin coating, dip coating, a bar coating method, a die coating method, a spray coating method, and an LB method, as well as methods such as screen printing, ink-jet printing and blade coating.

Of these, in terms of productivity preferred are a spin coating method, a blade coating method, a dip coating method, a roller coating method, a bar coating method and a die coating method which can simply and precisely form a thin film using an organic semiconductor solution.

When a precursor such as pentacene is soluble in a solvent as disclosed in Advanced Material 1999, Vol. 6, p. 480-483, a precursor layer formed by coating of the precursor solution may be heat treated to form an intended organic material layer.

In the invention, it is especially preferred that the organic semiconductor layer is formed according to an organic semiconductor solution casting method.

When the organic semiconductor layer is formed according to an organic semiconductor solution casting method, any arbitrary solvent can be used for a solvent of the organic semiconductor solution. The solvent is appropriately selected from a wide range of organic solvents such as hydrocarbons, alcohols, ethers, esters, ketones and glycol ethers due to kinds of the organic semiconductor compounds. Typically, chained ether solvents such as diethyl ether and diisopropyl ether, cyclic ether solvents such as tetrahydrofuran and dioxane, ketone solvents such as acetone, methyl ethyl ketone and cyclohexanone, aromatic solvents such as xylene, toluene, o-diachlorobenzene, nitrobenzene and meta-cresol, aliphatic hydrocarbon solvents such as hexane, cyclohexane and tridecane, α-terpineol, halogenated alkane solvents such as chloroform and 1,2-dichloroethane, N-methylpyrrolidone and carbon disulfide are suitably used.

It is preferred in coatability or layer forming properties on the gate insulating layer that the solvent contains an aliphatic organic solvent, for example, cyclohexane or hexane.

The thickness of the organic semiconductor layer is not specifically limited. Properties of the obtained transistor tend to depend significantly on the thickness of the organic semiconductor layer. The thickness is ordinarily at most 1 μm, and preferably from 10 to 300 nm, although it is different depending on kinds of the organic semiconductor.

In the invention, contact angle of the organic semiconductor layer surface to water is preferably 80° or more, and more preferably 90° or more. (Here, the contact angle to water means a value measured under the condition of 20° C. and 50% RH, using a contact angle meter TYPE CA-V or TYPE CA-DT•A, produced by Kyowa Interface Science Co., Ltd.). In order to adjust the water contact angle of the of the organic semiconductor layer surface, the surface may be subjected to treatment such as silane coupling agent treatment. Even if the organic semiconductor does not contain a functional group, adhesion of the silane coupling agent to the surface can adjust the contact angle.

Further, according to the organic semiconductor element of the present invention, at least one of the gate electrode and the source and drain electrodes is formed according to the method for manufacturing the organic semiconductor element of the present invention, whereby a low resistance electrode can be formed without lowering properties of the organic semiconductor layer.

In the organic thin film transistor of the present invention, a source electrode or a drain electrode is formed according to the above electroless plating method. However, the gate electrode or one of the source electrode and the drain electrode may be an electrode undergoing no electroless plating. The gate electrode and one of the source and the drain electrode are formed according to a conventional method employing electrode materials known in the art. The electrode materials are not specifically limited provided that the materials are electrically conductive. There are utilized platinum, gold, silver, nickel, chromium, copper, iron, tin, antimony lead, tantalum, indium, palladium, tellurium, rhenium, iridium, aluminum, ruthenium, germanium, molybdenum, tungsten, tin-antimony oxide, indium-tin oxide ITO, fluorine-doped zinc oxide, zinc, carbon, graphite, glassy carbon, silver paste and carbon paste, lithium, beryllium, sodium, magnesium, potassium, calcium, scandium, titanium, manganese, zirconium, gallium, niobium, sodium, sodium-potassium alloy, magnesium, lithium, aluminum, magnesium/copper mixtures, magnesium/silver mixtures, magnesium/aluminum mixtures, magnesium/indium mixtures, aluminum/aluminum oxide mixtures, and lithium/aluminum mixtures. Alternatively, there may preferably be utilized conductive polymers known in the art with electric conductivity enhanced via doping such as conductive polyaniline, conductive polypyrrole, or conductive polythiophene (including a complex of polyethylene dixoythiophene and polystyrenesulfonic acid).

As materials to form the source electrode or the drain electrode, those among materials described above are preferred which exhibit low electrical resistance in the interface to be in contact with the semiconductor layer. With regard to p-type semiconductors, platinum, gold, silver, ITO, conductive polymers and carbon are especially preferred.

With regard to the source electrode or the drain electrode, those formed using a fluid electrode material such as a solution, paste, ink or dispersion each containing the above conductive materials, specifically a fluid electrode material containing the conductive polymers or metal particles containing platinum, gold, silver or copper are preferred. Further, in order to protect an organic semiconductor from damage, those containing water in an amount of at least 60% and preferably at least 90% is preferred as solvents and dispersion media for the fluid electrode material.

For example, conductive pastes known in the art may be utilized as fluid electrode materials containing metal particles, but the materials are preferred in which metal particles with a particle diameter of from 1 to 50 nm, and preferably from 1 to 10 nm are dispersed in a dispersion medium such as water or any appropriate solvent, using a dispersion stabilizer, as necessary.

Usable materials for the metal particles include platinum, gold, silver, nickel, chromium, copper, iron, tin, antimony, lead, tantalum, indium, palladium, tellurium, rhenium, iridium, aluminum, ruthenium, germanium, molybdenum, tungsten and zinc.

Production methods of these metal particle dispersions include physical production methods such as an in-gas evaporation method, a sputtering method or a metal vapor synthesis method, and chemical production methods such as a colloid method or a co-precipitation method in which metal ions are reduced in a liquid phase to produce metal particles. Preferable are metal particle dispersions produced according to methods such as the colloid methods described in Japanese Patent O.P.I. Publication Nos. 11-76800, 11-80647, 11-319538 and 2000-239853, and the in-gas evaporation methods described in Japanese Patent O.P.I. Publication Nos. 2001-254185, 2001-53028, 2001-35255, 2000-124157 and 2000-123634. An electrode is formed using any of these metal particle dispersions, dried to remove the solvent and heated at a temperature of from 100 to 300° C. and preferably 150 to 200° C. in the shape thereof, as necessary, whereby the metal particles are heat-fused to form an electrode pattern of the targeted shape.

As methods of forming the electrode, there are a method in which the electrode is formed according to a known photolithography or lift-off method from an electrically conductive layer of the conductive material described above formed according to a vacuum deposition method or a sputtering method, and a method in which a resist is formed on a film of a metal such as aluminum or copper via heat transfer or inkjet printing, followed by etching. Further, patterning may be directly carried out according to an ink-jet printing method using a conductive polymer solution or dispersion or a dispersion containing metal particles, or the electrode may be formed from a coated layer according to lithography or laser ablation. Still further, it is possible to utilize a method in which the patterning is carried out via printing methods such as letterpress, intaglio, lithographic, or screen printing, using a conductive ink or paste containing conductive polymers or metal particles.

The source electrode and the drain electrode can be formed according to photolithography, wherein a light sensitive resin solution is coated on the entire surface of the organic semiconductor protective layer to form a light sensitive resin layer.

It is possible to use, as the light sensitive resin, the same resin as the known positive or negative working light sensitive resin above used in patterning the protective layer.

According to photolithography, subsequently, patterning is carried out using a metal particle-containing dispersion or a conductive polymer as a material for a source or drain electrode, optionally followed by heat fusion whereby an electrode is formed.

A solvent used to prepare a coating solution of the light sensitive resin layer and a method for forming the light sensitive resin layer are as described above in the patterning of the protective layer.

A light source for pattern exposure and a developing solution to develop the light sensitive resin layer, which are used after formation of the light sensitive resin layer, are also as described above in the patterning of the protective layer. Further, an ablation layer, which is another light sensitive resin layer, may be utilized for electrode formation. As the ablation layer, there are mentioned of those as described above in the patterning of the protective layer.

Various insulating films may be employed as the gate insulating film (layer) of the organic thin film transistor of the invention. The insulating layer is preferably an inorganic oxide film comprised of an inorganic oxide with high dielectric constant. Examples of the inorganic oxide include silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth niobate tantalate, and yttrium trioxide. Of these, silicon oxide, aluminum oxide, tantalum oxide or titanium oxide is preferred. An inorganic nitride such as silicon nitride or aluminum nitride can be also suitably used.

As methods for forming the above film, there are mentioned of a dry process including a vacuum deposition method, a molecular beam epitaxial growth method, an ion cluster beam method, a low energy ion beam method, an ion plating method, a CVD method, a sputtering method and an atmospheric pressure plasma method, and a wet process including a coating method such as a spray coating method, a spin coating method, a blade coating method, a dip coating method, a casting method, a roll coating method, an bar coating method or a die coating method, and a patterning method such as a printing method or an ink-jet method. These methods can be suitably applied due to kinds of materials used.

As the typical wet process can be used a method of coating an inorganic oxide particle dispersion, prepared by dispersing inorganic oxide particles in an organic solvent or water optionally in the presence of a dispersant such as a surfactant, followed by drying, or a so-called sol gel method of coating a solution of an oxide precursor such as an alkoxide, followed by drying.

Among the above, the preferred is the atmospheric pressure plasma method described above.

It is preferred that the gate insulating film (layer) is comprised of an anodized film or of a mixed film of an anodized film and an insulating film. The anodized film is preferably subjected to sealing treatment. The anodized film is formed by anodizing a metal capable of being anodized according to a known method.

Examples of the metal capable of being anodized include aluminum and tantalum. An anodization treatment method is not specifically limited and the known anodization treatment method can be used. Anodization treatment forms an oxidization film. An electrolytic solution used in the anodization treatment may be any as long as it can form a porous oxidation film. Examples of electrolytes in the electrolytic solution include sulfuric acid, phosphoric acid, oxalic acid, chromic acid, boric acid, sulfamic acid, benzene sulfonic acid or their salt, and an admixture of two or more kinds thereof. Anodization treatment conditions cannot be specified since they vary due to kinds of an electrolytic solution used. Generally, the concentration of the electrolytic solution is from 1 to 80% by weight, the temperature of the electrolytic solution is from 5 to 70° C., the current density is from 0.5 to 60 A/dm², the voltage applied is from 1 to 100 V, and the electrolytic time is from 10 seconds to 5 minutes. It is preferred that an aqueous solution of sulfuric acid, phosphoric acid or boric acid is used as an electrolytic solution, and direct current is used. Alternating current can be also used. The concentration in the aqueous solution of the above acids is preferably from 5 to 45% by weight. Anodization treatment is preferably carried out in the electrolytic solution at a current density of from 0.5 to 20 A/dm² at a temperature of from 20 to 50° C. for 20 to 250 seconds.

Examples of an organic compound used in the organic compound film include polyimide, polyamide, polyester, polyacrylate, photocurable resins of the photo-radical polymerization or photo-cation polymerization type, a copolymer containing an acrylonitrile unit, polyvinyl phenol, polyvinyl alcohol, novolak resin, and cyanoethylpullulan.

As a method of forming the organic compound film, the wet process described above is preferably used.

The inorganic oxide film and the organic oxide film can be used in combination and superposed. The thickness of the insulating film above is generally 50 nm to 3 μm, and preferably from 100 nm to 1 μm.

When an organic semiconductor layer is formed on a gate insulating film (layer), the gate insulating layer may be subjected to any surface treatment. A self-organizing orientation film is suitably used which is formed from a silane coupling agent such as octadecyltrichlorosilane or trichloromethylsilazane, alkane phosphoric acid, alkane sulfonic acid or alkane carboxylic acid.

Further, in order to obtain a gate insulating layer with a surface whose wettability to a solution containing an organic semiconductor material to be coated is high, the gate insulating layer is preferably subjected to surface treatment. Examples of such a surface treatment include surface roughening treatment for changing the surface roughness of the gate insulating layer, orientation treatment such as rubbing for forming a self-arranging thin film, and surface treatment employing a silane coupling agent.

Preferred examples of the silane coupling agent are octadecyltrichlorosilane, octyltrichlorosilane, hexamethyldisilane and hexamethyldisilazane, and the invention is not limited thereto. In the invention, surface treatment employing a silane coupling agent is preferred.

### (Substrate)

Various materials are usable as substrate materials to constituting a substrate. For example, employed may be ceramic substrates such as glass, quartz, aluminum oxide, sapphire, silicon nitride and silicon carbide; and semiconductor substrates such as silicon, germanium, gallium arsine and gallium nitrogen; paper; and unwoven cloth. In the present invention, it is preferred that the substrate is composed of resins. For example, a plastic film sheet film is usable. Examples of the plastic film include film comprised of, for example, polyethylene terephthalate (PET), polyethylene naphthalate (PEN), polyethersulfone (PES), polyetherimide, polyether ether ketone, polyphenylene sulfide, polyallylate, polyimide, polycarbonate (PC), cellulose triacetate (TAC), or cellulose acetate propionate (CAP). Use of such a plastic film makes it possible to decrease weight, to enhance portability, and to enhance durability against impact due to its flexibility, as compared to glass.

In the invention, a protective layer can be provided on the organic thin film transistor element of the invention. Materials for the protective layer include inorganic oxides or nitrides described above, and the protective layer is preferably formed according to the atmospheric pressure plasma method as described above, whereby durability of the organic thin film transistor is improved.

### <<Subbing Layer>>

It is preferred that the organic thin film transistor element of the invention comprises at least one of a subbing layer containing a compound selected from inorganic oxides or inorganic nitrides and a subbing layer containing a polymer.

Examples of the inorganic oxides contained in the subbing layer include silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth niobate tantalate, and yttrium trioxide. Examples of the inorganic nitrides include silicon nitride and aluminum nitride.

Of these, silicon oxide, aluminum oxide, tantalum oxide, titanium oxide or silicon nitride is preferred.

In the invention, the subbing layer containing a compound selected from inorganic oxides or inorganic nitrides is preferably formed according to the atmospheric pressure plasma method described above.

Examples of the polymer used in the subbing layer include a polyester resin, a polycarbonate resin, a cellulose resin, an acryl resin, a polyurethane resin, a polyethylene resin, a polypropylene resin, a polystyrene resin, a phenoxy resin, a norbornene resin, an epoxy resin, a vinyl polymer such as vinyl chloride-vinyl acetate copolymer, a vinyl chloride resin, vinyl acetate-vinyl alcohol copolymer, a partially saponified vinyl chloride-vinyl acetate copolymer, vinyl chloride-vinylidene chloride copolymer, vinyl chloride-acrylonitrile copolymer, ethylene-vinyl alcohol copolymer, polyvinyl alcohol, chlorinated polyvinyl chloride, ethylene-vinyl chloride copolymer or ethylene-vinyl acetate copolymer, a polyamide resin, a rubber resin such as an ethylene-butadiene resin or a butadiene-acrylonitrile resin, a silicone resin and a fluorine-contained resin.

### EXAMPLES

Next, the present invention will be explained employing examples, but is not specifically limited thereto. In the examples, “%” (represents “% by weight”, unless otherwise specified.

### Example 1

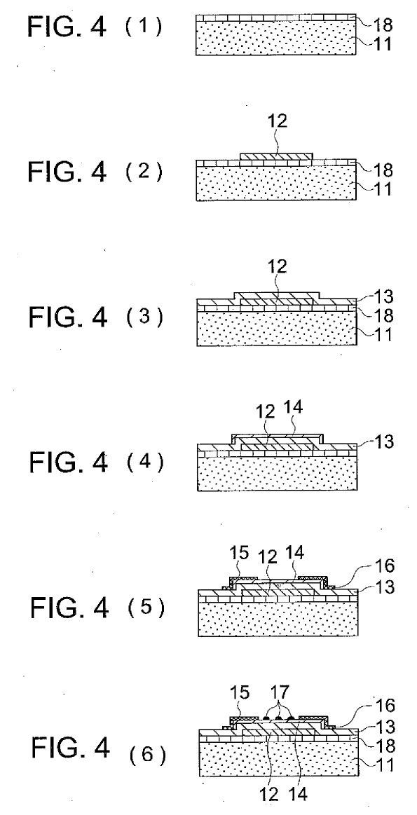

Explanation will be made employing FIG. 4.

A polyethersulfone resin film (200 μm) was used for resin substrate 11, and subjected to corona discharge under a condition of 50 W/m²/min. Then, a subbing layer was formed to enhance adhesion as follows.

### (Formation of Subbing Layer)

A coating solution having the following composition was coated on the substrate, dried at 90° C. for 5 minutes to obtain a dry thickness of 2 μm, and cured using a high pressure mercury lamp of 60 W/cm for 4 seconds at a distance of 10 cm from the lamp.

| | | |
|---|---|---|
| Dipentaerythritolhexaacrylate monomer | 60 | g |
| Dipentaerythritolhexaacrylate dimmer | 20 | g |
| Trimer or more of dipentaerythritolhexaacrylate | 20 | g |
| Diethoxybenzophenone UV initiator | 2 | g |
| Silicone- containing surfactant | 1 | g |
| Methyl ethyl ketone | 75 | g |
| Methylpropylene glycol | 75 | g |

Further, the resulting layer was subjected to atmospheric pressure plasma processing under the following conditions to form a silicon oxide layer with a thickness of 50 nm, which was designated as subbing layer 18 (FIG. 4(1)).

### (Gases Used)

Inert gas: helium 98.25% by volume
Reactive gas: oxygen gas 1.5% by volume
Reactive gas: tetraethoxysilane vapor 0.25% by volume
(bubbled with helium gas)
(Discharge conditions)
Discharge power: 10 W/cm²

### (Electrode Conditions)

The electrode was a grounded roll electrode having a dielectric material (specific dielectric constant: 10) with a smooth surface of an Rmax of 5 μm, wherein a stainless steel jacket roll base material having a cooling device employing chilled water was coated with a 1 mm thick alumina layer via ceramic spraying, further coated with a solution prepared by diluting tetramethoxysilane with ethyl acetate, and dried, followed by sealing treatment via ultraviolet irradiation. In contrast, a hollow square-shape stainless pipe having the same dielectric material as above was prepared in the same manner as above, whereby a voltage application electrode was obtained.

Subsequently, a gate electrode 12 was formed. Thus, light sensitive resin composition solution 1 having the following composition was coated on the subbing layer 18, and dried at 100° C. for 1 minute to form a light sensitive resin layer with a thickness of 2 μm. Then, exposure was carried out a pattern of using a 100 mW semiconductor laser of an 830 nm oscillation wavelength at an energy density of 200 mJ/cm² to form patterns of a gate line and a gate electrode, followed by development with an aqueous alkaline solution to obtain a resist image. Further, a 300 nm thick aluminum layer was formed entirely on the surface employing a sputtering method, followed by removing the residual light sensitive resin layer with MEK to prepare the gate busline and gate electrode 12 (FIG. 4(2)).

### (Light Sensitive Resin Composition Solution 1)

| | |
|---|---|
| Dye A | 7 parts |
| Novolak resin | 90 parts |
| (novolak resin prepared by co-polycondensation of phenol and a mixed cresol of m-cresol and | |
| p-cresol with formaldehyde (Mw = 4000; phenol/m-cresol/p-cresol = 5/57/38 (by molar ratio)) | |
| Crystal violet | 3 parts |
| Propylene glycol monomethyl ether | 1000 parts |

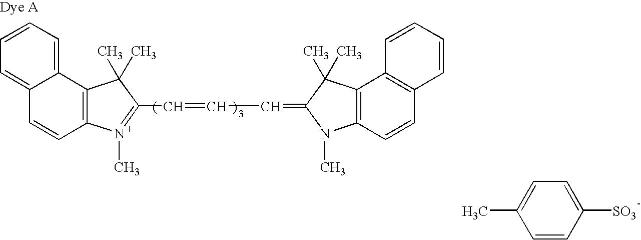

Further, instead of carrying out patterning via resist formation using a light sensitive resin, patterns of the gate line and gate electrode may be formed via the electroless plating method according to the method in the invention wherein the electroless plating method is used in combination with an electrostatic suction-type ink jet apparatus.

Subsequently, an anodized film (not illustrated) was formed on the gate electrode as an auxiliary insulation film for smoothing and insulation enhancing through the following anodized film formation process.

### (Anodized Film Formation Process)

After formation of the gate electrode, the substrate was sufficiently washed, and then anodization was carried out in a 10% by weight ammonium phosphate aqueous solution employing direct current supplied from a 30 V constant voltage power supply for 2 minutes to form an anodized film with a thickness of 120 nm. After sufficiently washed, the resulting film was subjected to vapor sealing treatment at 100° C. at normal pressure in a vapor-saturated chamber. Thus, a gate electrode with the anodized film was formed on a polyethersulfone resin substrate with a subbing layer.

Then, a silicon dioxide layer with a thickness of 30 nm was further formed at a film temperature of 200° C. according to the atmospheric pressure plasma method as described above to form a gate insulating layer 13 (FIG. 4(3)) with a thickness of 150 nm including the anodized aluminum film.

Thereafter, an organic semiconductor layer was formed on the gate insulating layer 13, employing Compound <1> described later as a semiconductor material. Namely, a toluene solution (0.5% by weight) of Compound <1> was ejected on the region where a channel was to be formed according to a piezo-type ink jet method, and dried at 50° C. for 3 minutes in nitrogen gas to form an organic semiconductor layer 14 with a thickness of 50 nm on the substrate (FIG. 4(4)). A contact angle of this organic semiconductor layer surface to water was 88%.

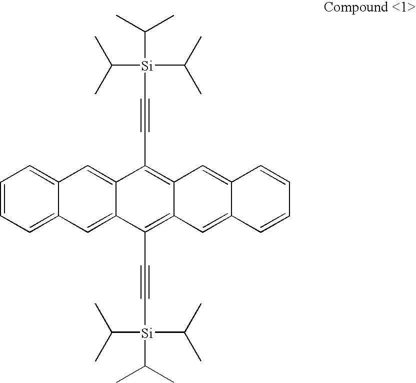

Subsequently, gold was vapor-deposited onto the semiconductor layer to form a source electrode 15 and a drain electrode 16 (FIG. 4(5)), each having a width of 30 μm, a length of 100 μm (channel width) and a thickness of 50 nm. The distance (channel length) between the source electrode 15 and a drain electrode 16 was 80 μm.

An aqueous dispersion of a complex of PEDOT (polyethylenedioxythiophene) with PSS (polystyrene sulfonic acid) (BAYTRON P produced by Bayer Co., Ltd.) was dropwise provided between the source and drain electrodes to form a coated film, followed by blade sliding, whereby the coated film was repelled to form a pattern as shown in FIG. 2(b). The resulting element was dried at 100° C. for 3 minutes in a nitrogen atmosphere to form a different-type electrode 17 (FIG. 4(6)).

The thin film transistor thus obtained was effectively driven, and exhibited a p-type enhancement operation. When the drain bias was set at −20V and the source bias was scanned from +10 to −40V, the drain current increase (transmission property) was observed. Mobility evaluated from the saturation region was 0.6 cm²/Vs.

### Example 2

The same procedures as Example 1 were carried out till the source and drain electrodes were formed, and then an aqueous dispersion of a complex of PEDOT (polyethylenedioxythiophene) with PSS (polystyrene sulfonic acid) (BAYTRON P produced by Bayer Co., Ltd.) was ejected between the source and drain electrodes through a piezo-type ink jet apparatus to form a liquid film, whereby the liquid film was repelled to form the same pattern as Example 1. Subsequently, the resulting element was dried at 100° C. for 3 minutes in a nitrogen atmosphere to form a different-type electrode. The thin film transistor thus obtained was effectively driven as in Example 1, and mobility evaluated from the saturation region was 0.7 cm²/Vs.

### Comparative Example 1

A thin film transistor was prepared in the same manner as in Example 1 above, except that the different type electrode was not formed. The mobility of this thin film transistor was 0.1 cm²/Vs, evaluated from the saturation region.

As is apparent from the above, the inventive organic thin film transistor (Example 1 or 2) has high carrier mobility, as compared with that of Comparative Example 1.

1. An organic thin film transistor comprising a substrate, a gate electrode, a gate insulating layer, an organic semiconductor layer, a source electrode, a drain electrode and at least one different type electrode, wherein the different type electrode is provided on the organic semiconductor layer and in a channel region between the source electrode and the drain electrode.

2. The organic thin film transistor of claim 1, wherein the different type electrode is independently provided.

3. The organic thin film transistor of claim 1, wherein the different type electrode is formed from fluid electrode materials.

4. The organic thin film transistor of claim 1, wherein the source electrode and the drain electrode are formed from fluid electrode materials.

5. The organic thin film transistor of claim 3, wherein the fluid electrode materials for forming the different type electrode contain water.

6. The organic thin film transistor of claim 1, wherein the contact angle of the organic semiconductor layer surface to water is at least 80°.

7. The organic thin film transistor of claim 1, wherein the organic semiconductor layer is a solution casting layer.

8. A method for manufacturing an organic thin film transistor comprising a substrate, a gate electrode, a gate insulating layer, an organic semiconductor layer, a source electrode, a drain electrode and at least one different type electrode, the method comprising the step of forming the different type electrode on the organic semiconductor layer and in a channel region between the source electrode and the drain electrode.

9. The organic thin film transistor of claim 1, wherein the gate electrode, the gate insulating layer and the organic semiconductor layer are provided on the substrate in that order, and the source electrode and the drain electrode are provided on the organic semiconductor layer and contact the gate insulating layer.

10. The organic thin film transistor of claim 9, wherein two or more of the different type electrode are provided on the organic semiconductor layer and in a channel region between the source electrode and the drain electrode.

11. The organic thin film transistor of claim 1, wherein the gate electrode, the gate insulating layer and the semiconductor layer are provided on the substrate in that order, and the source electrode and the drain electrode are provided on the gate insulating layer to contact the organic semiconductor layer.

12. The organic thin film transistor of claim 1, the source electrode comprising a first source electrode and a second source electrode and the drain electrode comprising a first drain electrode and a second drain electrode, wherein the gate electrode, the gate insulating layer and the organic semiconductor layer are provided on the substrate in that order, the first source electrode and the first drain electrode are provided on the gate insulating layer to contact the organic semiconductor layer, the second source electrode is provided on the organic semiconductor layer to contact the first source electrode, and the second drain electrode is provided on the organic semiconductor layer to contact the first drain electrode.
